(19) United States
(12) Patent Application Publication
(10) Pub. No.: US 2026/0133224 A1
(43) Pub. Date: May 14, 2026

(54) PROBE HEAD ASSEMBLY AND PROBE CARD ASSEMBLY

(71) Applicant: Taiwan Semiconductor Manufacturing Company, Ltd., Hsinchu (TW)

(72) Inventors: Kuan Chun Chen, Hsinchu City (TW); Shu An Shang, Kaohsiung City (TW); Guang-Sing Huang, Hsinchu County (TW); Kai-Yi Tang, New Taipei City (TW); Hsiou-Yu He, Hsinchu (TW)

(73) Assignee: Taiwan Semiconductor Manufacturing Company, Ltd., Hsinchu (TW)

(21) Appl. No.: 18/946,996

(22) Filed: Nov. 14, 2024

(51) Int. Cl. G01R 1/073; G01R 1/067

(52) U.S. Cl. CPC G01R 1/07314; G01R 1/0675

(57) ABSTRACT

A probe head assembly and a probe card assembly are provided. The probe head assembly includes a probe head structure, a sensor unit and conductive patterns. The probe head structure includes a first substrate, a second substrate and needles. The first substrate includes needle holes. The second substrate is spaced apart from the first substrate and includes needle holes corresponding to the needle holes of the first substrate. The needles extend through the needle holes of the first substrate and the needle holes of the second substrate. The sensor unit is mounted on the probe head structure. The conductive patterns are disposed on the probe head structure. The sensor unit is electrically connected to a first needle and a second needle among the needles through a first conductive pattern and a second conductive pattern among the conductive patterns, respectively.

### BACKGROUND

In general, semiconductor fabrication involves numerous steps including material deposition, photolithography, and etching to form a plurality of individual semiconductor devices or integrated circuit chips (dies) on a single semiconductor wafer. Some of the individual chips formed on the wafer, however, may have defects due to variances and problems that may arise during the intricate semiconductor fabrication process. Prior to wafer dicing in which the individual integrated circuit chips (dies) are separated from the semiconductor wafer, electrical performance and reliability tests are performed on a plurality of chips simultaneously, and the measurement data is transmitted to a test system to determine if a chip has a defect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 illustrate cross sectional views of intermediate stages in the manufacturing of a probe card assembly according to some embodiments of the present disclosure.

FIG. 7 illustrates a cross sectional view of the probe card assembly in FIG. 6 during a chip probing test.

FIG. 8 to FIG. 11 illustrate cross sectional views of intermediate stages in the manufacturing of a probe card assembly according to some embodiments of the present disclosure.

FIG. 12 illustrates a cross sectional view of the probe card assembly in FIG. 11 during a chip probing test.

FIG. 13 to FIG. 16 illustrate cross sectional views of intermediate stages in the manufacturing of a probe card assembly according to some embodiments of the present disclosure.

FIG. 17 illustrates a cross sectional view of the probe card assembly in FIG. 16 during a chip probing test.

FIG. 18 to FIG. 20 illustrate cross sectional views of three probe card assemblies according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A probe head and a probe card having the probe head are provided for performing a chip probing test (or an electrical test) on a device under test (DUT) such as a semiconductor wafer. For a probe card in which a sensor IC is mounted on a printed circuit board (PCB) that provides power to the sensor IC, the sensor IC cannot obtain data (or information) of the DUT under a probe head, data inside the probe head, or data inside the probe card due to the positional relationship between the sensor IC and the probe head (e.g., the probe head is disposed on the PCB and located next to the sensor IC) and the sensing range of the sensor IC. The data includes, for example, physical properties, optical properties or mechanical index related to the tested target such as the DUT, surface(s) or element(s) inside the probe head or surface(s) or element(s) inside the probe card. For example, the data includes surface temperature of the DUT, surface temperature of at least one of substrates in the probe head, temperature of at least one of needles in the probe head, a distance between the DUT and the probe head, a distance between substrates of the probe head, a distance between a space transformer of the probe card and the probe head, humidity inside the probe head, humidity inside the probe card, images showing contours of the chips in the DUT, images showing particles or defects on the chips, or the like. Even if the sensor IC is mounted on one of the substrates of the existing probe head, the sensor IC still cannot function properly because there is no circuitry on the substrates of the existing probe head to power the sensor IC.

In embodiments of the present disclosure, a sensor unit (e.g., a sensor IC) is mounted on the probe head structure, and a plurality of conductive patterns are disposed on the probe head structure to electrically connect the sensor unit to some needles in the probe head structure to provide power transmission paths for the sensor unit. As such, the sensor unit can function properly and can obtain data (or information) of the DUT under the probe head structure, data inside the probe head assembly, or data inside the probe card assembly. In some embodiments, the plurality of conductive patterns as well as the needles connected thereto are also configured to transmit the measurement data to an automatic control system which adjusts and controls the voltage, current, and/or frequency parameters of the probe card assembly through testing software, which can improve the stability of the test system and prevent chips or the probe card assembly from burning out during the testing process. In some alternative embodiments, a receiver unit (e.g., a receiver IC) is further included to receive the measurement data from the sensor unit through, for example, wireless transmission and to transmit the measurement data to the automatic control system.

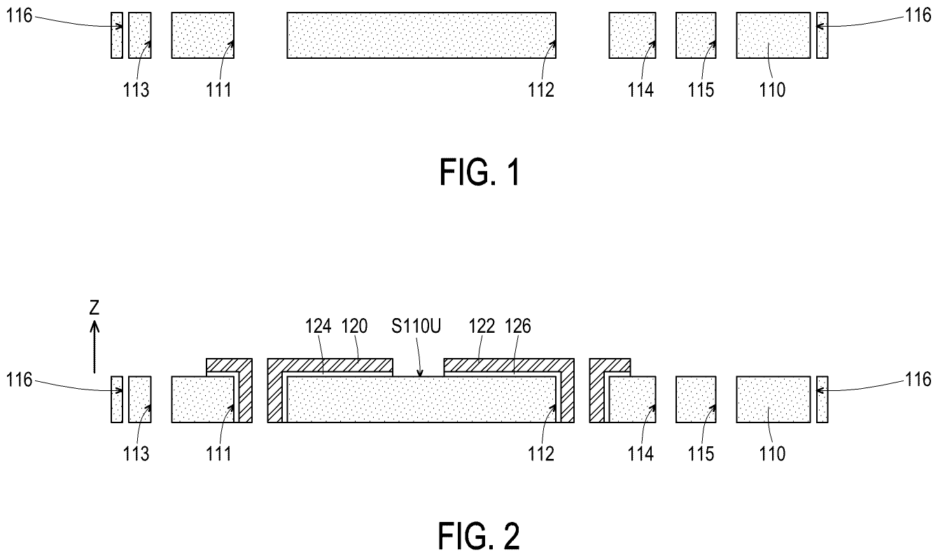

FIG. 1 to FIG. 6 illustrate cross sectional views of intermediate stages in the manufacturing of a probe card assembly according to some embodiments of the present disclosure. It is understood that additional operations can be provided before, during, and after the processes shown by FIG. 1 to FIG. 6, and some of the operations described below can be replaced or eliminated, for additional embodiments of the method. The order of the operations/processes may be interchangeable.

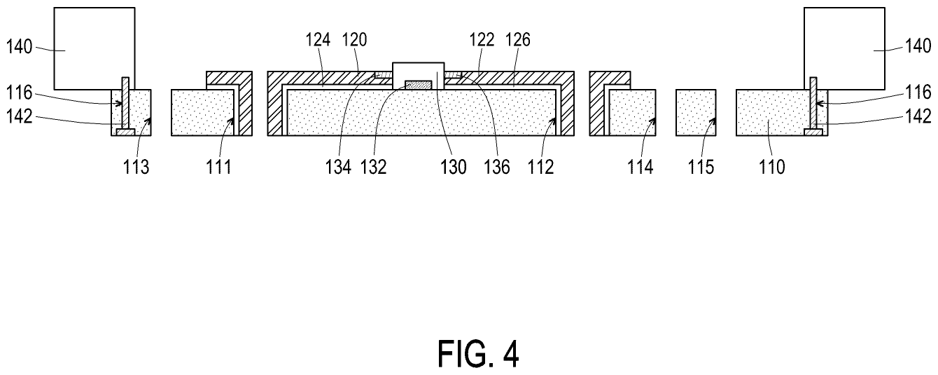

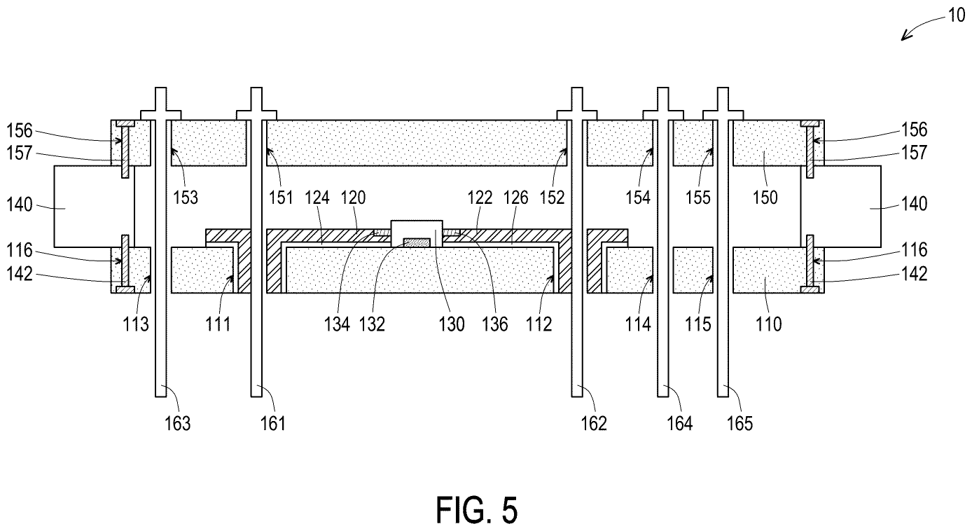

Referring to FIG. 1, a lower substrate 110 (or referred to as “lower die”) is provided. The lower substrate 110 includes a plurality of lower through holes (e.g., a lower through hole 111 to lower through holes 116) configured for various purposes. For example, the lower through hole 111, the lower through hole 112, the lower through hole 113, the lower through hole 114 and the lower through hole 115 among the plurality of lower through holes are needle holes through which a plurality of subsequently formed needles (e.g., a needle 161, a needle 162, a needle 163, a needle 164 and a needle 165 shown in FIG. 5) can pass; and the lower through holes 116 among the plurality of lower through holes are a plurality of assembling holes in which a plurality of subsequently formed fixing elements (e.g., a plurality of fixing elements 142 shown in FIG. 4) can fix, but the present disclosure is not limited in this respect.

The lower substrate 110 can be made with a single layer or multiple layers of ceramic material or other suitable materials. For example, when the lower substrate 110 is thick, the lower substrate 110 can be formed by adhering multiple substrates formed with multiple through holes, wherein the multiple through holes in the multiple substrates are aligned with each other before adhering the multiple substrates. By separately forming (e.g., laser drilling) multiple through holes in the multiple substrates, and then fixing (e.g., pasting) the multiple substrates together, the feasibility of the through hole formation process can be improved or the difficulty of the through hole formation process can be reduced.

Referring to FIG. 2, a plurality of conductive patterns are formed on the lower substrate 110. For example, the plurality of conductive patterns includes a first conductive pattern 120 and a second conductive pattern 122 spaced apart and electrically isolated from the first conductive pattern 120. In some embodiments, as shown in FIG. 2, the first conductive pattern 120 and the second conductive pattern 122 are formed on an upper surface S110U of the lower substrate 110 and respectively extend into the lower through hole 111 and the lower through hole 112, but the present disclosure is not limited in this respect.

The plurality of conductive patterns may belong to the same conductive layer(s) and may be formed together in the same processes. Each of the plurality of conductive patterns may be made with a single layer or multiple layers of conductive material, and electrically conductivity of the conductive material is above 10\hat{ }6 (S/m), i.e., electrically conductivity ≥10\hat{ }6 (S/m). In some embodiments, the conductive material includes various materials, such as gold (Au), tungsten (W), aluminum (Al), silver (Ag), titanium (Ti), or the like, and the formation methods may include sputtering, printing, electroplating, electroless plating, and/or chemical vapor deposition (CVD) methods, but the present disclosure is not limited in this respect.

In some embodiments, as shown in FIG. 2, a plurality of adhesive patterns (including a first adhesive pattern 124 and a second adhesive pattern 126) can be formed between the lower substrate 110 and the plurality of conductive patterns (including the first conductive pattern 120 and the second conductive pattern 122) to improve adhesion between the plurality of conductive patterns and the lower substrate 110 or to improve the peeling of the plurality of conductive patterns from the lower substrate 110.

For example, the plurality of adhesive patterns may be formed on the lower substrate 110 prior to the formation of the plurality of conductive patterns (including the first conductive pattern 120 and the second conductive pattern 122), wherein the plurality of adhesive patterns includes the first adhesive pattern 124 disposed between the first conductive pattern 120 and the lower substrate 110 and the second adhesive pattern 126 disposed between the second conductive pattern 122 and the lower substrate 110. In some embodiments, as shown in FIG. 2, orthogonal projections of the first adhesive pattern 124 and the first conductive pattern 120 on the lower substrate 110 along a thickness direction (e.g., a direction Z) of the overall structure are substantially the same, and orthogonal projections of the second adhesive pattern 126 and the second conductive pattern 122 on the lower substrate 110 along the direction Z are substantially the same.

The plurality of adhesive patterns may belong to the same adhesive layer(s) and may be formed together in the same processes. Each of the plurality of adhesive patterns may be made with a single layer or multiple layers of adhesive material. For example, each of the plurality of adhesive patterns may include a first adhesive layer configured to improve the adhesion to the lower substrate 110, a second adhesive layer configured to block impurity diffusion and a third adhesive layer configured to improve the adhesion to the corresponding conductive pattern, wherein the first adhesive layer, the second adhesive layer and the third adhesive layer are sequentially stacked on the lower substrate 110 along the direction Z. In some embodiments, the adhesive material includes various metals, such as chromium (Cr), titanium (Ti), aluminum (Al), nickel (Ni), tungsten (W), platinum (Pt), gold (Au), any combination thereof, or the like, and the formation methods may include electrolytic plating, electroless plating, sputtering, CVD methods, PVD methods, or the like.

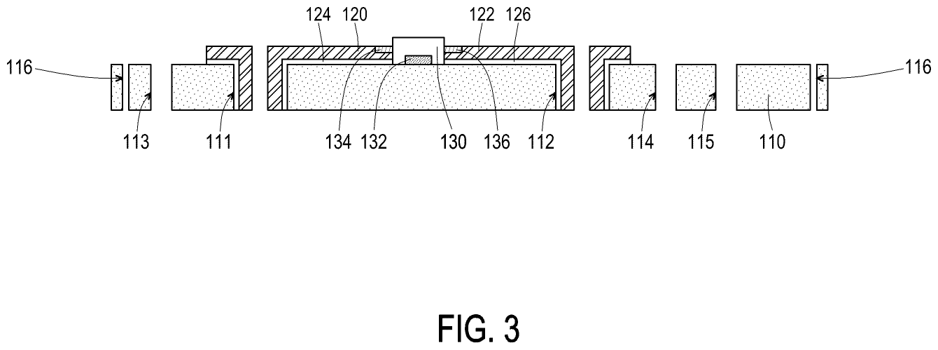

Referring to FIG. 3, a sensor unit 130 is mounted on the lower substrate 110. The sensor unit 130 is configure to detect or obtain data (or information) of the tested target such as a device under test (DUT), surface(s) or element(s) inside the probe head or surface(s) or element(s) inside the probe card. The data includes, for example, temperature, distance(s), humidity, image(s), and/or the like, but the present disclosure is not limited in this respect. Correspondingly, the sensor unit 130 may include various sensors to detect or obtain required data.

In some embodiments, as shown in FIG. 3, the sensor unit 130 is disposed between the first conductive pattern 120 (as well as the first adhesive pattern 124) and the second conductive pattern 122 (as well as the second adhesive pattern 126). In other words, the first conductive pattern 120 (as well as the first adhesive pattern 124) and the second conductive pattern 122 (as well as the second adhesive pattern 126) are spaced apart from each other through the sensor unit 130. In this way, the first conductive pattern 120 (as well as the first adhesive pattern 124) and the second conductive pattern 122 (as well as the second adhesive pattern 126) can maintain independent electrical properties and short circuiting between the first conductive pattern 120 (as well as the first adhesive pattern 124) and the second conductive pattern 122 (as well as the second adhesive pattern 126) can be avoided.

The sensor unit 130 may be a sensor IC that includes a sensor 132, a contact pad (e.g., a solder pad or the like) 134 and a contact pad (e.g., a solder pad or the like) 136, but the present disclosure is not limited in this respect. The sensor unit 130 may include one or more elements to provide other functions. For example, in embodiments in which the sensor 132 is a light sensor, the sensor unit 130 may further include a light emitter having an emission wavelength corresponding to the receive wavelength of the light sensor.

In some embodiments, the sensor 132 is located on a bottom side of the sensor unit 130 and closer to the lower substrate 110 than the contact pad 134 and the contact pad 136. In embodiments in which the lower substrate 110 is an opaque substrate (e.g., a ceramic substrate), the sensor 132 may be a temperature sensor that detects surface temperature of the lower substrate 110, but not limited thereto.

One of the contact pad 134 and the contact pad 136 corresponds to a positive electrode of the sensor unit 130, and the other one of the contact pad 134 and the contact pad 136 corresponds to a negative electrode of the sensor unit 130. The contact pad 134 and the contact pad 136 may be in contact with the first conductive pattern 120 and the second conductive pattern 122, respectively. For example, the contact pad 134 and the contact pad 136 may be embedded in the first conductive pattern 120 and the second conductive pattern 122, respectively. In FIG. 3, the contact pad 134 and the contact pad 136 are located on left and right sides of the sensor unit 130, and the sensor 132 is on the bottom side of the sensor unit 130. However, the positions of the sensor 132, the contact pad 134 and the contact pad 136 with respect to the sensor unit 130 may be changed according to needs/designs. In other embodiments, the contact pad 134 and the contact pad 136 may be located on the bottom side or a top side of the sensor unit 130. In addition, the sensor 132 may be located on the left side, the right side, the top side, the bottom side or the combination of the above (e.g., when the number of the sensor 132 is more than one) of the sensor unit 130 depending on the type and/or application of the sensor 132.

Referring to FIG. 4, the lower substrate 110 is fixed to a spacer 140. For example, the lower substrate 110 is fixed to the spacer 140 using screws or other suitable fixing elements 142, the fixing elements 142 extend through the lower through holes 116 of the lower substrate 110 and into the spacer 140. The spacer 140 may be made of metal, such as aluminum or other suitable materials.

Referring to FIG. 5, an upper substrate 150 (or referred to as “upper die”) is provided and mounted over the lower substrate 110 through the spacer 140. The spacer 140 keeps the upper substrate 150 apart from the lower substrate 110 by a distance. In embodiments in which the sensor unit 130 is disposed between the upper substrate 150 and the lower substrate 110, the distance is greater than a thickness of the sensor unit 130 to reserve space for placement and heat dissipation of the sensor unit 130.

The upper substrate 150 includes a plurality of upper through holes (e.g., an upper through hole 151 to upper through holes 156) configured for various purposes. For example, the upper through hole 151, the upper through hole 152, the upper through hole 153, the upper through hole 154 and the upper through hole 155 among the plurality of upper through holes are needle holes corresponding to the plurality of lower through holes (e.g., the lower through hole 111 to the lower through hole 115) of the lower substrate 110 and through which a plurality of needles (e.g., the needle 161, the needle 162, the needle 163, the needle 164 and the needle 165) can pass; and the upper through holes 156 among the plurality of upper through holes are a plurality of assembling holes in which a plurality of subsequently formed fixing elements (e.g., a plurality of fixing elements 157) can fix, but the present disclosure is not limited in this respect.

The upper substrate 150 can be made with a single layer or multiple layers of ceramic material or other suitable materials. For example, when the upper substrate 150 is thick, the upper substrate 150 can be formed by adhering multiple substrates formed with multiple through holes, wherein the multiple through holes in the multiple substrates are aligned with each other before adhering the multiple substrates. By separately forming (e.g., laser drilling) multiple through holes in the multiple substrates, and then fixing (e.g., pasting) the multiple substrates together, the feasibility of the through hole formation process can be improved or the difficulty of the through hole formation process can be reduced.

In some embodiments, the upper substrate 150 can be fixed to the spacer 140 using screws or other suitable fixing elements 157, the fixing elements 157 extend through the upper through holes 156 of the upper substrate 150 and into the spacer 140. Alternatively, the upper substrate 150, the spacer 140, and the lower substrate 110 can be fixed together using one set of fixing elements.

The plurality of needles (e.g., the needle 161, the needle 162, the needle 163, the needle 164 and the needle 165) are provided and extend through the plurality of lower through holes (e.g., the lower through hole 111 to the lower through hole 115) and the plurality of upper through holes (e.g., the upper through hole 151 to the upper through hole 155). As shown in FIG. 5, the needle 161 extend through the lower through hole 111 and the upper through hole 151, wherein an upper end of the needle 161 protrude out of the upper through hole 151, and a lower end of the needle 161 protrude out of the lower through hole 111. The needle 162 extend through the lower through hole 112 and the upper through hole 152, wherein an upper end of the needle 162 protrude out of the upper through hole 152, and a lower end of the needle 162 protrude out of the lower through hole 112. The relative arrangement of other needles (e.g., the needle 163, the needle 164 and the needle 165) and the corresponding through holes can be deduced in the same way and will not be repeated here.

In some embodiments, the needle 161 and the needle 162 are electrical connection needles configured to electrically connect the sensor unit 130 to the test system to power the sensor unit 130; the needle 163 is an I/O needle configured to carry operating signals, in particular input/output signals, between the test system and the device under test; the needle 164 is a power needle configured to carry power signal towards the device under test; and the needle 165 is a ground needle configured to carry ground signal towards the device under test, but the claimed scope is not limited in this respect.

At this point, the manufacturing of a probe head assembly 10 is substantially done. The probe head assembly 10 includes a probe head structure (including a first substrate, a second substrate and a plurality of needles), the sensor unit 130 and the plurality of conductive patterns (including the first conductive pattern 120 and the second conductive pattern 122). The first substrate (referred to a substrate of the probe head assembly 10 not disposed with the sensor unit 130 and the plurality of conductive patterns such as the upper substrate 150 shown in FIG. 5) includes a plurality of needle holes (e.g., the upper through hole 151 to the upper through hole 155). The second substrate (referred to a substrate of the probe head assembly 10 disposed with the sensor unit 130 and the plurality of conductive patterns such as the lower substrate 110 shown in FIG. 5) is spaced apart from the first substrate and includes a plurality of needle holes (e.g., the lower through hole 111 to the lower through hole 115) corresponding to the plurality of needle holes of the first substrate. The plurality of needles (e.g., the needle 161 to the needle 165) extend through the plurality of needle holes of the first substrate and the plurality of needle holes of the second substrate. The sensor unit 130 is mounted on the probe head structure (e.g., on the lower substrate 110). The plurality of conductive patterns are disposed on the probe head structure (e.g., on the lower substrate 110). The sensor unit 130 is electrically connected to a first needle (e.g., the needle 161) and a second needle (e.g., the needle 162) among the plurality of needles through the first conductive pattern 120 and the second conductive pattern 122 among the plurality of conductive patterns, respectively.

In some embodiments, as shown in FIG. 5, the sensor unit 130 is mounted on the second substrate (e.g., the lower substrate 110). The plurality of conductive patterns (including the first conductive pattern 120 and the second conductive pattern 122) are disposed on the second substrate (e.g., the lower substrate 110). The probe head assembly 10 further includes a first adhesive pattern 124 disposed between the first conductive pattern 120 and the second substrate (e.g., the lower substrate 110) and a second adhesive pattern 126 disposed between the second conductive pattern 122 and the second substrate (e.g., the lower substrate 110).

In some embodiments, the first needle (e.g., the needle 161) and the first conductive pattern 120 contact in a first needle hole (e.g., the lower through hole 111) among the plurality of needle holes (e.g., the lower through hole 111 to the lower through hole 115) of the second substrate (e.g., the lower substrate 110), and the second needle (e.g., the needle 162) and the second conductive pattern 122 contact in a second needle hole (e.g., the lower through hole 112) among the plurality of needle holes (e.g., the lower through hole 111 to the lower through hole 115) of the second substrate (e.g., the lower substrate 110).

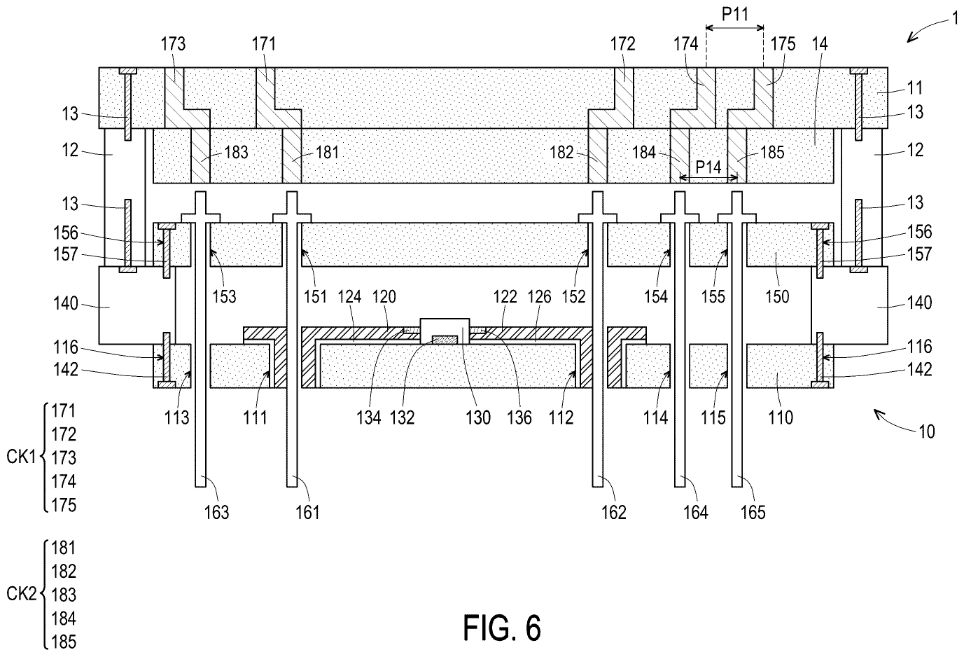

Referring to FIG. 6, after the probe head assembly 10 of FIG. 5 is assembled, the probe head assembly 10 can be further assembled to a jig 12 of FIG. 6 to be connected to a circuit board 11 and form a probe card assembly 1. The jig 12 may be a mounting ring mounted on the circuit board 11 through fixing elements 13, and the probe head assembly 10 is fixed to the circuit board 11 through the jig 12. In detail, the spacer 140 is mounted on the jig 12 through the fixing elements 13 for connecting the probe head assembly 10 to the circuit board 11. The jig 12 keeps the probe head assembly 10 apart from the circuit board 11.

At this point, the manufacturing of the probe card assembly 1 is substantially done. The probe card assembly 1 includes the circuit board 11 and the probe head assembly 10 described above but the present disclosure is not limited in this respect. Optionally, as shown in FIG. 6, the probe card assembly 1 further includes a space transformer 14 disposed between the circuit board 11 and the probe head assembly 10 and spaced apart from the probe head assembly 10.

The space transformer 14 is disposed on a surface of the circuit board 11 facing the probe head assembly 10 and may be a multi-layered organic (MLO) or multi-layered ceramic (MLC) interconnect substrate. The space transformer 14 may be configured to fan-in the wirings of the circuit board 11 so that the plurality of needles (e.g., the needle 161, the needle 162, the needle 163, the needle 164 and the needle 165) in the probe head assembly 10 can be mated with testing pads on a device under tested. In some embodiments, although not shown in FIG. 6, the space transformer 14 includes a lower surface with a fine pitch C4 contact test pad array for engaging and mating with contact ends (upper ends) of the probe head assembly 10, and an upper surface with a ball grid array (BGA) for mating with corresponding contacts on the circuit board 11. A pitch of the contacts (BGA array) on the upper surface of the space transformer 14 may be greater than a pitch of the contacts (C4 contact test pad array) on the lower surface of the space transformer 14.

In some embodiments, the circuit board 11 includes a circuitry CK1, the space transformer 14 includes a circuitry CK2, the first needle (e.g., the needle 161) and the second needle (e.g., the needle 162) are electrically connected to different wirings (e.g., a wiring 171 and a wiring 172) of the circuitry CK1 of the circuit board 11 through different wirings (e.g., a wiring 181 and a wiring 182) of the circuitry CK2 of the space transformer 14, and a line pitch (e.g., a minimum distance between two middle lines of two adjacent wirings (e.g., a wiring 174 and a wiring 175)) P11 at a surface of the circuit board 11 away from the space transformer 14 is larger than a line pitch (e.g., a minimum distance between two middle lines of two adjacent wirings (e.g., a wiring 184 and a wiring 185)) P14 at a surface of the space transformer 14 away from the circuit board 11.

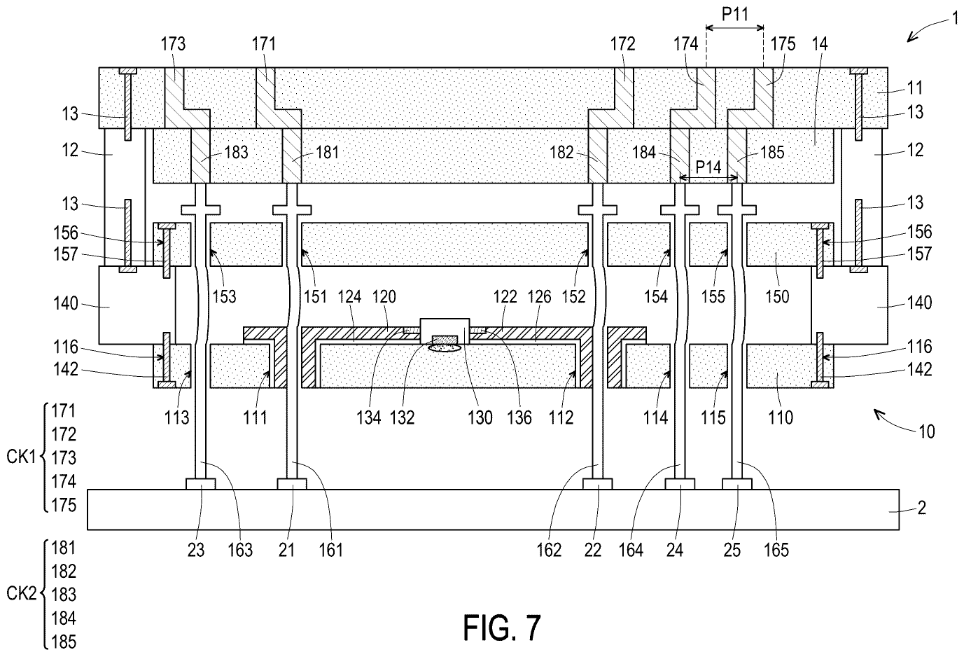

Specifically, as shown in FIG. 6, the circuitry CK1 may include a plurality of wirings such as the wiring 171, the wiring 172, a wiring 173, the wiring 174 and the wiring 175, and the circuitry CK2 of the space transformer 14 may include a plurality of wirings such as the wiring 181, the wiring 182, a wiring 183, the wiring 184 and the wiring 185 electrically connected to the wiring 171, the wiring 172, the wiring 173, the wiring 174 and the wiring 175, respectively. The wiring 181, the wiring 182, the wiring 183, the wiring 184 and the wiring 185 are disposed corresponding to the needle 161, the needle 162, the needle 163, the needle 164 and the needle 165. Before bringing the probe card assembly 1 into contact with a device under tested (e.g., DUT 2 shown in FIG. 7) to perform a chip probing test, the needle 161, the needle 162, the needle 163, the needle 164 and the needle 165 may be floating and separated from the wiring 181, the wiring 182, the wiring 183, the wiring 184 and the wiring 185, but the present disclosure is not limited in this respect. On the other hand, when bringing the probe card assembly 1 into contact with the DUT 2, as shown in FIG. 7, upper ends of the needle 161, the needle 162, the needle 163, the needle 164 and the needle 165 contact the wiring 181, the wiring 182, the wiring 183, the wiring 184 and the wiring 185, and lower ends of the needle 161, the needle 162, the needle 163, the needle 164 and the needle 165 contact testing pads (e.g., a testing pad 21, a testing pad 22, a testing pad 23, a testing pad 24 and a testing pad 25 shown in FIG. 7) on the DUT 2. Alternatively, the needle 161, the needle 162, the needle 163, the needle 164 and the needle 165 may be in contact with the wiring 181, the wiring 182, the wiring 183, the wiring 184 and the wiring 185 before bringing the probe card assembly 1 into contact with the DUT 2 shown in FIG. 7.

FIG. 7 illustrates a cross sectional view of the probe card assembly 1 in FIG. 6 during a chip probing test. Although not shown in FIG. 7, the circuit board 11 of the probe card assembly 1 may be electrically connected to a test system or an automatic control system.

As shown in FIG. 7, during the chip probing test, a force is applied to bring the probe card assembly 1 into contact with the DUT 2. Accordingly, upper end and lower end of each of the plurality of needles touch the DUT 2 and the space transformer 14, respectively, thereby forming a plurality of signal transmission paths through which signals from the test system or the automatic control system can be transmitted to the DUT 2.

Specifically, operating signals, in particular input/output signals, can be transmitted to the testing pad 23 of the DUT 2 sequentially through the wiring 173 in the circuit board 11, the wiring 183 in the space transformer 14 and the needle 163. Power signal can be transmitted to the testing pad 24 of the DUT 2 sequentially through the wiring 174 in the circuit board 11, the wiring 184 in the space transformer 14 and the needle 164. Ground signal can be transmitted to the testing pad 25 of the DUT 2 sequentially through the wiring 175 in the circuit board 11, the wiring 185 in the space transformer 14 and the needle 165. Further, power signals can be transmitted to the sensor unit 130 respectively through a first power transmission path composed of the wiring 171 in the circuit board 11, the wiring 181 in the space transformer 14, the needle 161 and the first conductive pattern 120, and a second power transmission path composed of the wiring 172 in the circuit board 11, the wiring 182 in the space transformer 14, the needle 162 and the second conductive pattern 122. Moreover, the needle 161 and the needle 162 can also be used to transmit measurement data from the sensor unit 130 to the automatic control system (e.g., tester or prober).

The force applied to bring the probe card assembly 1 into contact with the DUT 2 may cause each of the plurality of needles to bend, which can force the first needle (e.g., the needle 161) to contact the first conductive pattern 120 on at least one side within the first needle hole (e.g., the lower through hole 111) and force the second needle (e.g., the needle 162) to contact the second conductive pattern 122 on at least one side within the second needle hole (e.g., the lower through hole 112), but the present disclosure is not limited in this respect. Various parameters (e.g., thicknesses of the plurality of conductive patterns within the plurality of needle holes, widths of the plurality of needle holes or the like) can be adjusted or controlled to ensure the electrical connection between the first conductive pattern 120 and the first needle (e.g., the needle 161) and the electrical connection between the second conductive pattern 122 and the second needle (e.g., the needle 162).

In FIG. 7, the first substrate (e.g., the upper substrate 150) is disposed between the second substrate (e.g., the lower substrate 110) and the circuit board 11, the second substrate is, for example, an opaque substrate (e.g., a ceramic substrate), and the sensor unit 130 is mounted on the upper surface (e.g., a surface away from the DUT 2) of the second substrate (e.g., the lower substrate 110). In 14

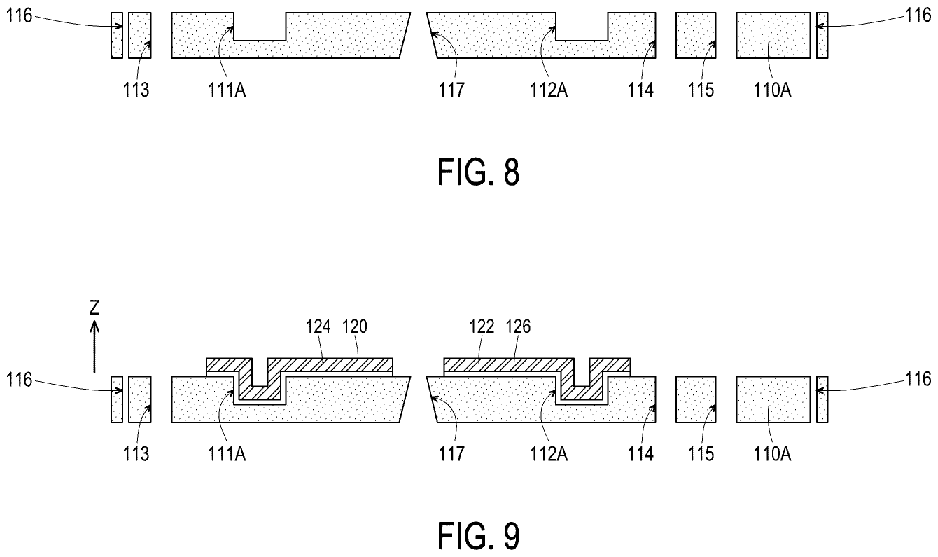

FIG. 8 to FIG. 11 illustrate cross sectional views of intermediate stages in the manufacturing of a probe card assembly according to some embodiments of the present disclosure. It is understood that additional operations can be provided before, during, and after the processes shown by FIG. 8 to FIG. 11, and some of the operations described below can be replaced or eliminated, for additional embodiments of the method. The order of the operations/processes may be interchangeable. Material, configuration, dimensions and/or processes the same as or similar to the foregoing embodiments described with FIG. 1 to FIG. 6 may be employed in the following embodiments, and detailed explanation thereof may be omitted.

Referring to FIG. 8, a lower substrate 110A (or referred to as “lower die”) is provided. The lower substrate 110A includes a first needle groove 111A, a second needle groove 112A, the lower through hole 113, the lower through hole 114, the lower through hole 115, the plurality of lower through holes 116 and a sensor hole 117. In some embodiments, although not shown in FIG. 8, the lower substrate 110A can include a plurality of sensor holes 117.

The first needle groove 111A and the second needle groove 112A are configured to carry the first conductive pattern 120 and the second conductive pattern 122, respectively. Therefore, the first needle groove 111A and the second needle groove 112A are blind holes that ends in the lower substrate 110A to provide surfaces to carry the first conductive pattern 120 and the second conductive pattern 122. Therefore, a depth of each of the first needle groove 111A and the second needle groove 112A is smaller than a thickness of the lower substrate 110A, and the first needle groove 111A and the second needle groove 112A are shallower than the lower through hole 113, the lower through hole 114, the lower through hole 115 and the plurality of lower through holes 116 that penetrate the lower substrate 110A.

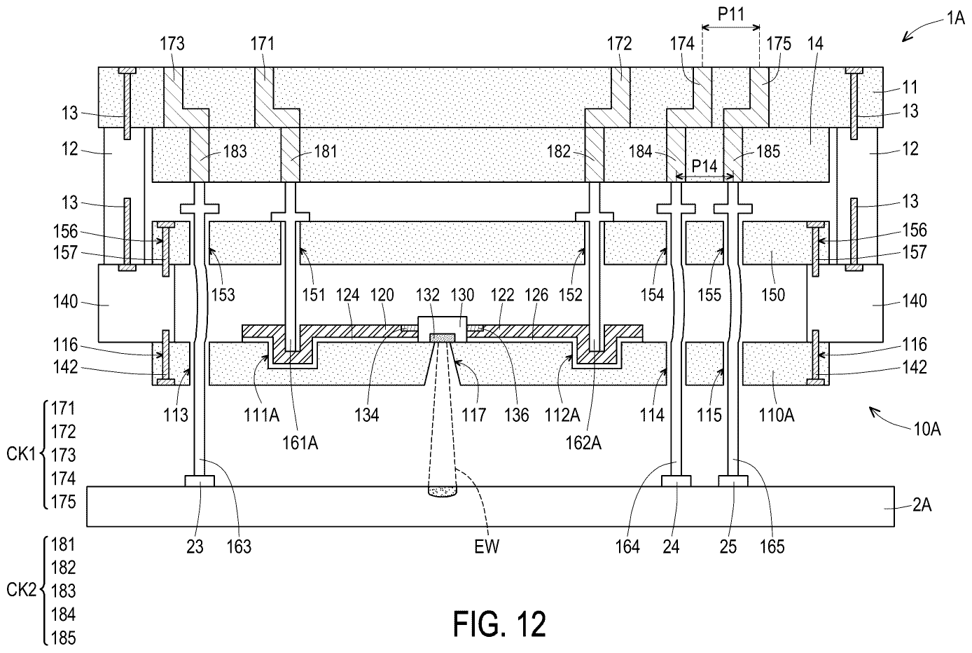

The sensor hole 117 is configured to allow electromagnetic waves (e.g., visible light, infrared light, microwave or the like depending on the application or function of the sensor 132) to pass through. For example, as shown in FIG. 12, the sensor hole 117 is overlapped with the sensor unit 130, so that electromagnetic waves EW emitted from an emitter (not shown) in the sensor unit 130 can pass through the lower substrate 110A through the sensor hole 117 and arrive at the DUT 2A. In addition, electromagnetic waves EW reflected by the DUT 2A can pass through the lower substrate 110A through the sensor hole 117 and be received by the sensor 132 of the sensor unit 130. Therefore, the sensor hole 117 is a through hole that passes through the lower substrate 110A. Namely, a depth of the sensor hole 117 may be equal to the thickness of the lower substrate 110A, and the first needle groove 111A and the second needle groove 112A are also shallower than the sensor hole 117 that penetrates the lower substrate 110A.

Referring to FIG. 9, the first conductive pattern 120 and the second conductive pattern 122 are formed on the lower substrate 110A. Optionally, the first adhesive pattern 124 and the second adhesive pattern 126 may be formed on the lower substrate 110A prior to the formation of the first conductive pattern 120 and the second conductive pattern 122 to improve adhesion between the plurality of conductive patterns and the lower substrate 110A or to improve the peeling of the plurality of conductive patterns from the lower substrate 110A. At this point, the sensor hole 117 is neither covered by the first adhesive pattern 124 and the second adhesive pattern 126 nor covered by the first conductive pattern 120 and the second conductive pattern 122.

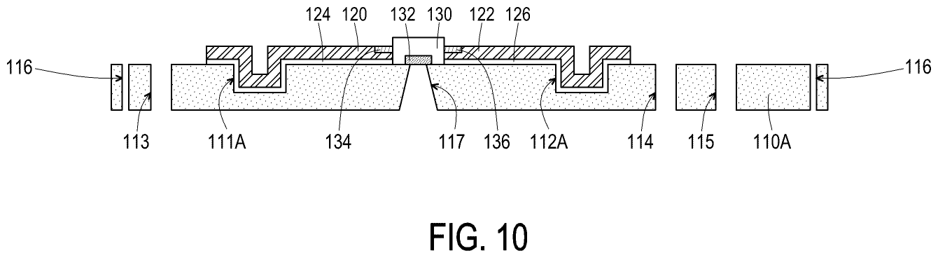

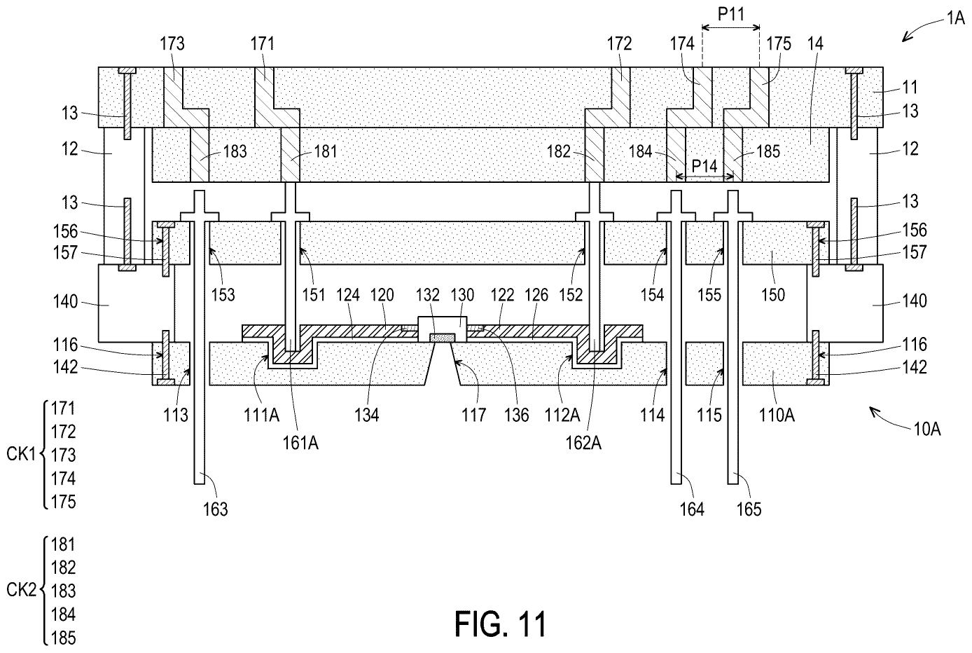

Referring to FIG. 10, the sensor unit 130 is mounted on the lower substrate 110A and overlapped with the sensor hole 117. After the sensor unit 130 is mounted on the lower substrate 110A, the steps of fixing the lower substrate 110A to the spacer 140 (e.g., the step shown in FIG. 4), mounting the upper substrate 150 (or referred to as “upper die”) to the lower substrate 110A through the spacer 140 (e.g., the step shown in FIG. 5) and providing the plurality of needles such as a needle 161A, a needle 162A, the needle 163, the needle 164 and the needle 165 (e.g., the step shown in FIG. 5) can be sequentially carried on to form a probe head assembly 10A, as shown in FIG. 11.

In the probe head assembly 10A, the lower substrate 110A is served as the second substrate on which the sensor unit 130 and the plurality of conductive patterns are disposed. The second substrate (e.g., the lower substrate 110A) further includes the first needle groove 111A and the second needle groove 112A. The first conductive pattern 120 and the second conductive pattern 122 are disposed in the first needle groove 111A and the second needle groove 112A, respectively. The first needle (e.g., the needle 161A) lands on the first conductive pattern 120 in the first needle groove 111A, and the second needle (e.g., the needle 162A) lands on the second conductive pattern 122 in the second needle groove 112A. In some embodiments, as shown in FIG. 11, the sensor unit 130 is disposed on a surface (e.g., an upper surface) of the second substrate (e.g., the lower substrate 110A) facing the first substrate (e.g., the upper substrate 150). The second substrate (e.g., the lower substrate 110A) is opaque to electromagnetic waves EW received by the sensor unit 130, and the second substrate (e.g., the lower substrate 110A) further includes the sensor hole 117 overlapped with the sensor unit 130 to allow the electromagnetic waves EW to pass through.

After the probe head assembly 10A is assembled, the probe head assembly 10A can be assembled to the jig 12 to be connected to the circuit board 11 and form a probe card assembly 1A. Optionally, as shown in FIG. 11, the probe card assembly 1A further includes the space transformer 14 disposed between the circuit board 11 and the probe head assembly 10A. After the probe card assembly 1A is assembled and before forcing the probe card assembly 1A into contact with the DUT 2A, an upper end of the first needle (e.g., the needle 161A) may be in contact with the wiring 181 in the space transformer 14, and a lower end of the first needle (e.g., the needle 161A) may be in contact with the first conductive pattern 120 in the first needle groove 111A; similarly, an upper end of the second needle (e.g., the needle 162A) may be in contact with the wiring 182 in the space transformer 14, and a lower end of the second needle (e.g., the needle 162A) may be in contact with the second conductive pattern 122 in the second needle groove 112A.

FIG. 12 illustrates a cross sectional view of the probe card assembly 1A in FIG. 11 during a chip probing test. Although not shown in FIG. 12, the circuit board 11 of the probe card assembly 1A may be electrically connected to a test system or an automatic control system.

As shown in FIG. 12, during the chip probing test, a force is applied to bring the probe card assembly 1A into contact with the DUT 2A.

In FIG. 12, the first substrate (e.g., the upper substrate 150) is disposed between the second substrate (e.g., the lower substrate 110A) and the circuit board 11, the second substrate is, for example, opaque to electromagnetic waves EW received by the sensor unit 130, and the sensor hole 117 is provided between the sensor unit 130 and the DUT 2A. In embodiments shown in FIG. 12, the sensor 132 of the sensor unit 130 may be a distance sensor configured to measure the distance between the lower substrate 110A and the DUT 2A to confirm the warpage of the lower substrate 110A (when multiple sensors or sensor units are included). Alternatively, the sensor 132 of the sensor unit 130 may be an image sensor configured to capture images (e.g., images showing contours of the chips in the DUT 2A, images showing particles or defects on the chips, or the like) of the DUT 2A. Alternatively, the sensor 132 can detect other physical properties, optical properties or mechanical index related to the tested target such as the DUT 2A, surface(s) or element(s) inside the probe head assembly 10A or surface(s) or element(s) inside the probe card assembly 1A.

In some embodiments, the first power transmission path (composed of the wiring 171 in the circuit board 11, the wiring 181 in the space transformer 14, the needle 161A and the first conductive pattern 120) and the second power transmission path (composed of the wiring 172 in the circuit board 11, the wiring 182 in the space transformer 14, the needle 162A and the second conductive pattern 122) can further be configured to transmit the measurement data to an automatic control system which adjusts and controls the voltage, current, and/or frequency parameters of the probe card assembly through testing software, which can improve the stability of the test system and prevent chips or the probe card assembly from burning out during the testing process. For example, the sensor 132 could detect distance between the probe head assembly 10A and the DUT 2A, the measurement data can be transmitted to an automatic control system through the first power transmission path and the second power transmission path, the automatic control system then evaluates the warpage of the probe head assembly 10A based on the measurement data and then adjusts and controls the voltage, current, and/or frequency parameters of the probe card assembly 1A through testing software to avoid the damage of the probe head assembly 10A and the DUT 2A.

In the probe card assembly 1A, the first needle (e.g., the needle 161A) lands on the first conductive pattern 120 in the first needle groove 111A without passing through the second substrate (e.g., the lower substrate 110A); similarly, the second needle (e.g., the needle 162A) lands on the second conductive pattern 122 in the second needle groove 112A without passing through the second substrate (e.g., the lower substrate 110A). As a result, the first needle (e.g., the needle 161A) and the second needle (e.g., the needle 162A) are shorter than other needles (e.g., the needle 163, the needle 164 and the needle 165) among the plurality of needles in the probe head assembly 10A. In addition, the DUT 2A do not need the testing pad (or referred to as “bump”) 21 and the testing pad (or referred to as “bump”) 22 shown in FIG. 6 or FIG. 7, which helps to free up more space, allowing the density of chips on the DUT 2A to be further increased (if needed).

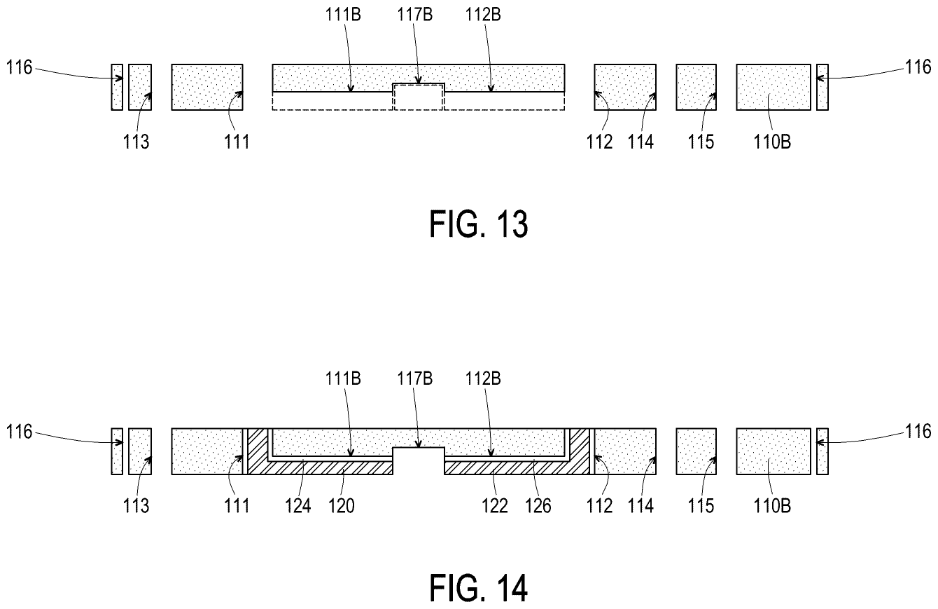

FIG. 13 to FIG. 16 illustrate cross sectional views of intermediate stages in the manufacturing of a probe card assembly according to some embodiments of the present disclosure. It is understood that additional operations can be provided before, during, and after the processes shown by FIG. 13 to FIG. 16, and some of the operations described below can be replaced or eliminated, for additional embodiments of the method. The order of the operations/processes may be interchangeable. Material, configuration, dimensions and/or processes the same as or similar to the foregoing embodiments described with FIG. 1 to FIG. 6 may be employed in the following embodiments, and detailed explanation thereof may be omitted.

Referring to FIG. 13, a lower substrate 110B (or referred to as “lower die”) is provided. The lower substrate 110B further includes a first conductive pattern groove 111B, a second conductive pattern groove 112B and a sensor groove 117B in addition to the lower through hole 111 to the lower through holes 116. The first conductive pattern groove 111B is connected between the first needle hole (e.g., the lower through hole 111) and the sensor groove 117B. The second conductive pattern groove 112B is connected between the second needle hole (e.g., the lower through hole 112) and the sensor groove 117B. In some embodiments, although not shown in FIG. 13, the lower substrate 110B can include a plurality of sensor grooves 117B.

The first conductive pattern groove 111B, the second conductive pattern groove 112B and the sensor groove 117B are configured to carry the first conductive pattern 120, the second conductive pattern 122 and the sensor unit 130, respectively. Therefore, the first conductive pattern groove 111B, the second conductive pattern groove 112B and the sensor groove 117B are blind holes that ends in the lower substrate 110B to provide surfaces to carry the first conductive pattern 120, the second conductive pattern 122 and the sensor unit 130. Therefore, a depth of each of the first conductive pattern groove 111B, the second conductive pattern groove 112B and the sensor groove 117B is smaller than a thickness of the lower substrate 110B, and the first conductive pattern groove 111B, the second conductive pattern groove 112B and the sensor groove 117B are shallower than the lower through hole 111, the lower through hole 112, the lower through hole 113, the lower through hole 114, the lower through hole 115 and the plurality of lower through holes 116 that penetrate the lower substrate 110B. The depth of the sensor groove 117B may be the same as or different from the depth of each of the first conductive pattern groove 111B and the second conductive pattern groove 112B.

In some embodiments, as shown in FIG. 13, the first conductive pattern groove 111B, the second conductive pattern groove 112B and the sensor groove 117B may be formed on the lower surface (a surface away from the upper substrate) of the lower substrate 110B, but the present disclosure is not limited in this respect. In other embodiments, the first conductive pattern groove 111B, the second conductive pattern groove 112B and the sensor groove 117B may be formed on the upper surface (a surface facing the upper substrate) of the lower substrate 110B.

Referring to FIG. 14, the first conductive pattern 120 and the second conductive pattern 122 are formed on the lower substrate 110B and respectively fill in the first needle hole (e.g., the lower through hole 111) and the second needle hole (e.g., the lower through hole 112). Optionally, the first adhesive pattern 124 and the second adhesive pattern 126 may be formed on the lower substrate 110B prior to the formation of the first conductive pattern 120 and the second conductive pattern 122 to improve adhesion between the plurality of conductive patterns and the lower substrate 110B or to improve the peeling of the plurality of conductive patterns from the lower substrate 110B. Further, the first conductive pattern 120 may fill the space in the first needle hole (e.g., the lower through hole 111) not occupied by the first adhesive pattern 124, and the second conductive pattern 122 may fill the space in the second needle hole (e.g., the lower through hole 112) not occupied by the second adhesive pattern 126. At this point, the sensor groove 117B is neither covered by the first adhesive pattern 124 and the second adhesive pattern 126 nor covered by the first conductive pattern 120 and the second conductive pattern 122.

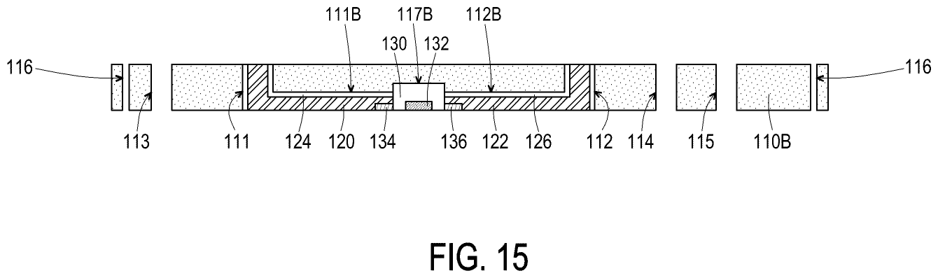

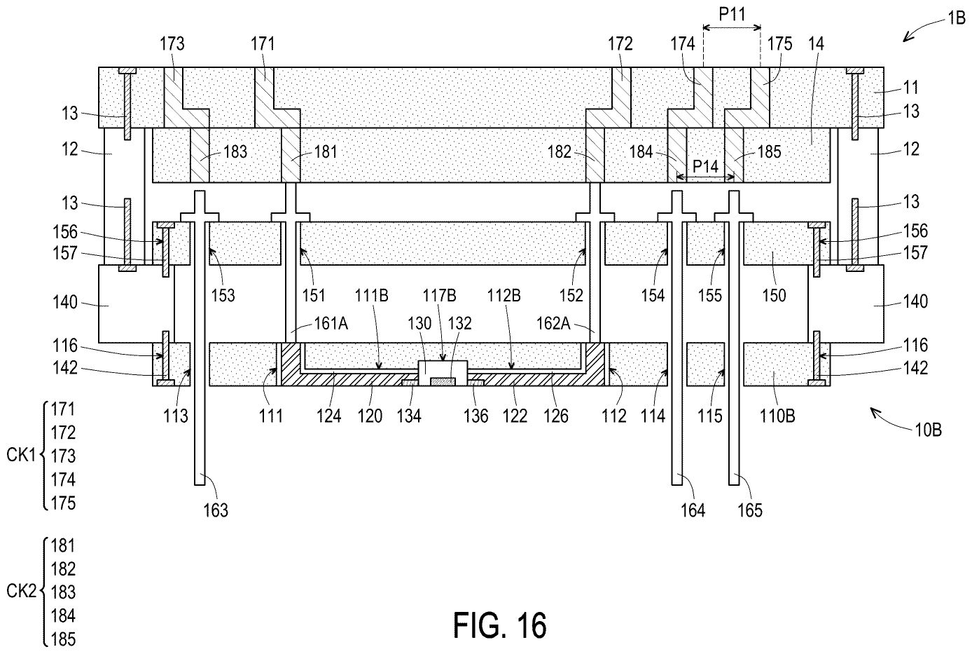

Referring to FIG. 15, the sensor unit 130 is mounted on a lower surface of the lower substrate 110B and placed in the sensor groove 117B. In some embodiments, although not shown, the sensor unit 130 may be attached in the sensor groove 117B through an adhesive layer (e.g., an insulating adhesive layer). After the sensor unit 130 is mounted to the lower substrate 110B, the steps of fixing the lower substrate 110B to the spacer 140 (e.g., the step shown in FIG. 4), mounting the upper substrate 150 (or referred to as “upper die”) to the lower substrate 110B through the spacer 140 (e.g., the step shown in FIG. 5) and providing the plurality of needles such as the needle 161A, the needle 162A, the needle 163, the needle 164 and the needle 165 (e.g., the step shown in FIG. 5) can be sequentially carried on to form a probe head assembly 10B, as shown in FIG. 16.

In the probe head assembly 10B, the lower substrate 110B is served as the second substrate on which the sensor unit 130 and the plurality of conductive patterns are disposed. A surface (e.g., a lower surface) of the second substrate (e.g., the lower substrate 110B) away from the first substrate (e.g., the upper substrate 150) includes the first conductive pattern groove 111B, the second conductive pattern groove 112B and the sensor groove 117B. The first conductive pattern groove 111B is connected between the first needle hole (e.g., the lower through hole 111) among the plurality of needle holes of the second substrate (e.g., the lower substrate 110B) and the sensor groove 117B. The second conductive pattern groove 112B is connected between a second needle hole (e.g., the lower through hole 112) among the plurality of needle holes of the second substrate (e.g., the lower substrate 110B) and the sensor groove 117B. The sensor unit 130 is disposed in the sensor groove 117B. The first conductive pattern 120 is disposed in the first conductive pattern groove 111B and extends into the first needle hole (e.g., the lower through hole 111). The second conductive pattern 122 is disposed in the second conductive pattern groove 112B and extends into the second needle hole (e.g., the lower through hole 112). In other words, the sensor unit 130 and the plurality of conductive patterns (including the first conductive pattern 120 and the second conductive pattern 122) are disposed in a plurality of grooves (including the first conductive pattern groove 111B, the second conductive pattern groove 112B and the sensor groove 117B) on a surface (e.g., a lower surface) of the second substrate (e.g., the lower substrate 110B) away from the first substrate (e.g., the upper substrate 150). The first needle (e.g., the needle 161A) lands on the first conductive pattern 120 in the first needle hole (e.g., the lower through hole 111), and the second needle (e.g., the needle 162A) lands on the second conductive pattern 122 in the second needle hole (e.g., the lower through hole 112). The plurality of needles (including the first needle and the second needle, i.e., the needle 161A and the needle 162A) landing on the plurality of conductive patterns and the sensor unit 130 are located on opposite sides of the second substrate (e.g., the lower substrate 110B). For example, the plurality of needles (including the first needle and the second needle, i.e., the needle 161A and the needle 162A) landing on the plurality of conductive patterns are located on an upper side of the second substrate (e.g., the lower substrate 110B), while the sensor unit 130 is located on a lower side of the second substrate (e.g., the lower substrate 110B).

After the probe head assembly 10B is assembled, the probe head assembly 10B can be assembled to the jig 12 to be connected to the circuit board 11 and form a probe card assembly 1B. Optionally, as shown in FIG. 16, the probe card assembly 1B further includes the space transformer 14 disposed between the circuit board 11 and the probe head assembly 10B. After the probe card assembly 1B is assembled and before forcing the probe card assembly 1B into contact with the DUT 2A, an upper end of the first needle (e.g., the needle 161A) may be in contact with the wiring 181 in the space transformer 14, and a lower end of the first needle (e.g., the needle 161A) may be in contact with the first conductive pattern 120 in the first needle hole (e.g., the lower through hole 111); similarly, an upper end of the second needle (e.g., the needle 162A) may be in contact with the wiring 182 in the space transformer 14, and a lower end of the second needle (e.g., the needle 162A) may be in contact with the second conductive pattern 122 in the second needle hole (e.g., the lower through hole 112).

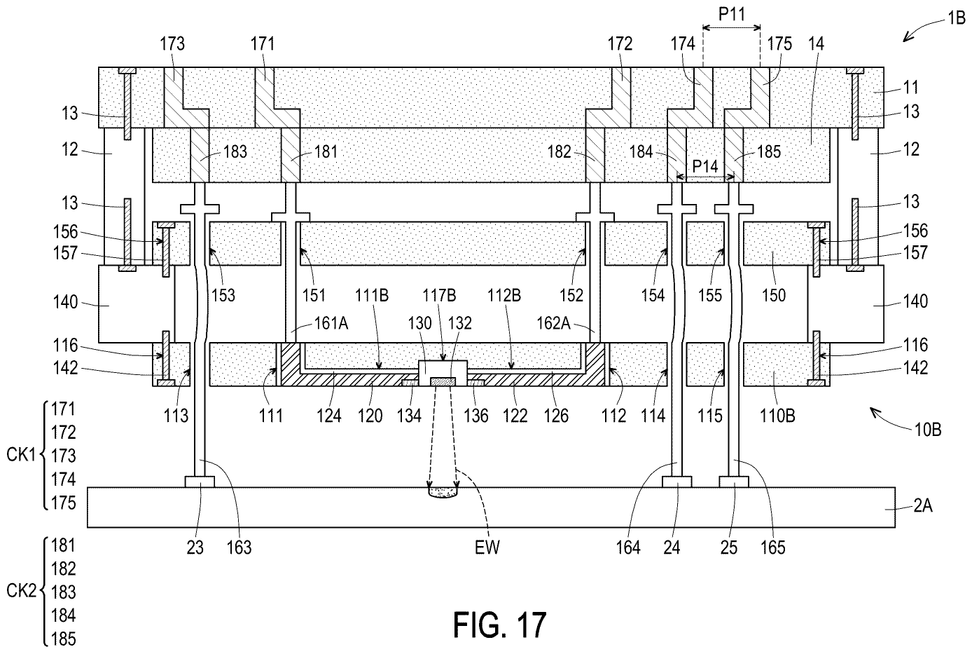

FIG. 17 illustrates a cross sectional view of the probe card assembly 1B in FIG. 16 during a chip probing test. Although not shown in FIG. 17, the circuit board 11 of the probe card assembly 1B may be electrically connected to a test system or an automatic control system.

As shown in FIG. 17, during the chip probing test, a force is applied to bring the probe card assembly 1B into contact with the DUT 2A.

In FIG. 17, the first substrate (e.g., the upper substrate 150) is disposed between the second substrate (e.g., the lower substrate 110B) and the circuit board 11, the second substrate is, for example, opaque to electromagnetic waves EW received by the sensor unit 130, and the sensor groove 117B is provided on the lower surface of the second substrate (e.g., the lower substrate 110B) so that the second substrate (e.g., the lower substrate 110B) opaque to electromagnetic waves EW is not located between the sensor unit 130 and the DUT 2A. In embodiments shown in FIG. 17, the sensor 132 of the sensor unit 130 may be a distance sensor configured to measure the distance between the lower substrate 110B and the DUT 2A to confirm the warpage of the lower substrate 110B (when multiple sensors or sensor units are included). Alternatively, the sensor 132 of the sensor unit 130 may be an image sensor configured to capture images (e.g., images showing contours of the chips in the DUT 2A, images showing particles or defects on the chips, or the like) of the DUT 2A. Alternatively, the sensor 132 can detect other physical properties, optical properties or mechanical index related to the tested target such as the DUT 2A, surface(s) or element(s) inside the probe head assembly 10B or surface(s) or element(s) inside the probe card assembly 1B.

In some embodiments, the first power transmission path (composed of the wiring 171 in the circuit board 11, the wiring 181 in the space transformer 14, the needle 161A and the first conductive pattern 120) and the second power transmission path (composed of the wiring 172 in the circuit board 11, the wiring 182 in the space transformer 14, the needle 162A and the second conductive pattern 122) can further be configured to transmit the measurement data to an automatic control system which adjusts and controls the voltage, current, and/or frequency parameters of the probe card assembly through testing software, which can improve the stability of the test system and prevent chips or the probe card assembly from burning out during the testing process.

In the probe card assembly 1B, the first needle (e.g., the needle 161A) and the second needle (e.g., the needle 162A) are shorter than other needles (e.g., the needle 163, the needle 164 and the needle 165) among the plurality of needles in the probe head assembly 10B. In addition, the DUT 2A do not need the testing pad (or referred to as “bump”) 21 and the testing pad (or referred to as “bump”) 22 shown in FIG. 6 or FIG. 7, which helps to free up more space, allowing the density of chips on the DUT 2A to be further increased (if needed).

In the embodiments in which the sensor unit 130, the first conductive pattern 120 and the second conductive pattern 122 are formed on the lower surface of the lower substrate, a distance can be kept between the probe head assembly 10B and the DUT 2A by forming the first conductive pattern groove 111B, the second conductive pattern groove 112B and the sensor groove 117B on the lower surface of the lower substrate, which can reduce the chance of the sensor unit 130 touching the DUT 2A during the chip probing test.

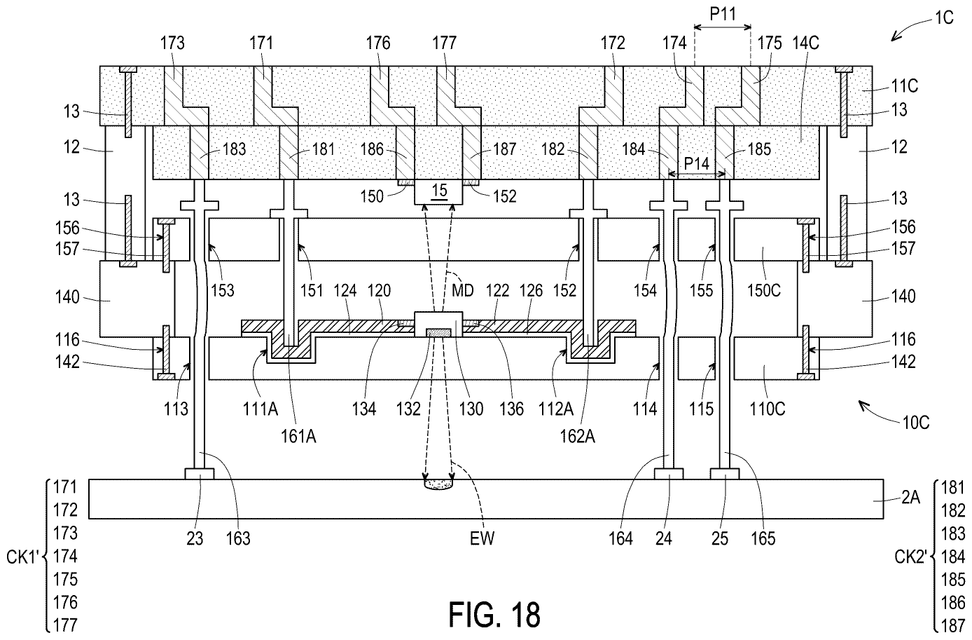

FIG. 18 to FIG. 20 illustrate cross sectional views of three probe card assemblies according to some embodiments of the present disclosure. Although not shown in FIG. 18 to FIG. 20, the circuit board 11 of the probe card assembly may be electrically connected to a test system or an automatic control system.

Referring to FIG. 18, a probe card assembly 1C is provided. The probe card assembly 1C is similar to the probe card assembly 1A in FIG. 12. However, in the probe card assembly 1C, at least one of the first substrate (e.g., an upper substrate 150C) and the second substrate (e.g., a lower substrate 110C) is transparent to electromagnetic waves EW received by the sensor unit 130. For example, the lower substrate 110C is transparent to electromagnetic waves EW received by the sensor unit 130 so that the electromagnetic waves EW reflected by the DUT 2A can pass through the lower substrate 110C and be received by the sensor unit 130 without the need to form the sensor hole 117 shown in FIG. 12. For example, the transparency of the lower substrate 110C to the electromagnetic waves EW received by the sensor unit 130 is more than 70%.

In some embodiments, as shown in FIG. 18, the probe card assembly 1C further includes a receiver unit 15 disposed between the circuit board 11C and the probe head assembly 10C. For example, the receiver unit 15 is mounted on a space transformer 14C, wherein a contact pad (e.g., a solder pad or the like) 150 and a contact pad (e.g., a solder pad or the like) 152 of the receiver unit 15 are electrically connected to a wiring 186 and a wiring 187 in a circuitry CK2′ of the space transformer 14C, respectively. In addition, the wiring 186 and the wiring 187 in the circuitry CK2′ of the space transformer 14C are electrically connected to a wiring 176 and a wiring 177 in a circuitry CK1′ of the circuit board 11C, respectively. In some embodiments, although not shown in FIG. 18, the probe card assembly 1C can include a plurality of receiver units 15, a plurality of sensor units 130 or a combination of the above.

The receiver unit 15 may be a receiver IC configured to receive the measurement data MD from the sensor unit 130 through, for example, wireless transmission and to transmit the measurement data MD to the automatic control system (not shown) through the wirings (e.g., the wiring 186 and the wiring 187) in the space transformer 14C and the wirings (e.g., the wiring 176 and the wiring 177) in the circuit board 11C.

In the embodiments in which the receiver unit 15 is included, the upper substrate 150C may also be transparent to the electromagnetic waves EW received by the sensor unit 130 so that the measurement data MD (corresponding to the electromagnetic waves EW) can pass through the upper substrate 150C and be received by the receiver unit 15 without the need to form a through hole in a region of the upper substrate overlapping the receiver unit 15. For example, the transparency of the upper substrate 150C to the electromagnetic waves EW received by the sensor unit 130 is more than 70%.

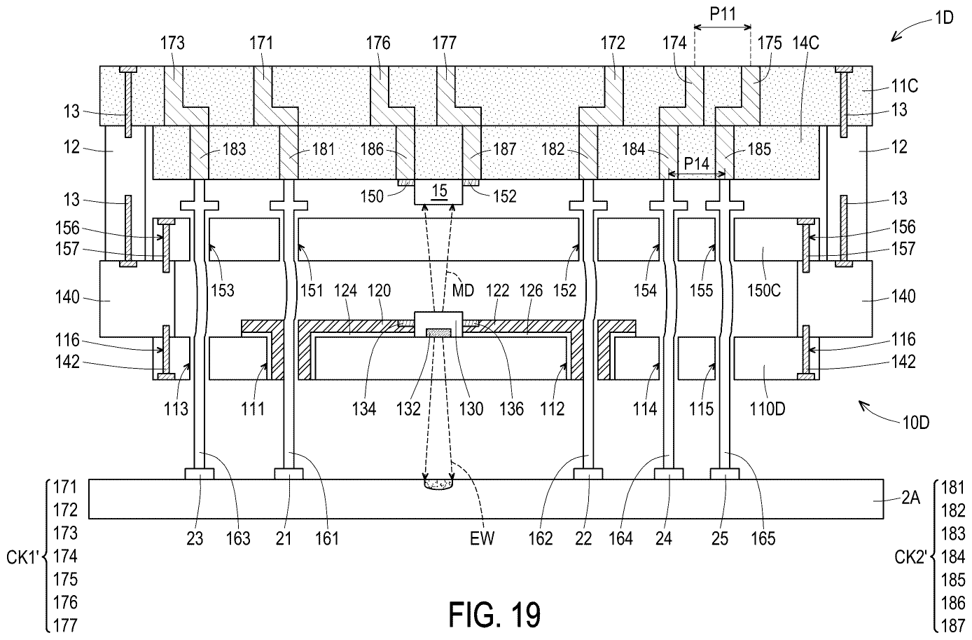

Referring to FIG. 19, a probe card assembly 1D is provided. The probe card assembly 1D is similar to the probe card assembly 1 in FIG. 7. However, in the probe card assembly 1D, at least one of the first substrate (e.g., an upper substrate 150C) and the second substrate (e.g., a lower substrate 110D) is transparent to electromagnetic waves EW received by the sensor unit 130. For example, the lower substrate 110D is transparent to electromagnetic waves EW received by the sensor unit 130 so that the electromagnetic waves EW reflected by the DUT 2 can pass through the lower substrate 110D and be received by the sensor unit 130 without the need to form the sensor hole 117 shown in FIG. 12.

In some embodiments, as shown in FIG. 19, the probe card assembly 1D further includes the receiver unit 15 disposed between the circuit board 11C and the probe head assembly 10D, and the upper substrate 150C may also be transparent to the electromagnetic waves EW received by the sensor unit 130 so that the measurement data MD (corresponding to the electromagnetic waves EW) can pass through the upper substrate 150C and be received by the receiver unit 15 without the need to form a through hole in a region of the upper substrate overlapping the receiver unit 15.

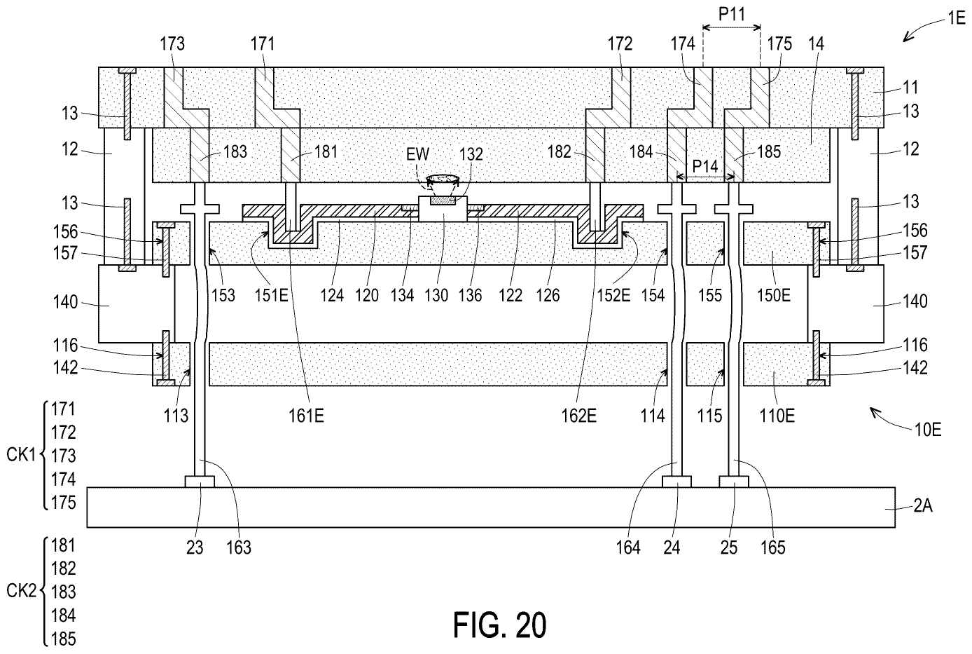

Referring to FIG. 20, a probe card assembly 1E is provided. The probe card assembly 1E is similar to the probe card assembly 1A in FIG. 12. However, in the probe card assembly 1E, an upper substrate 150E is served as the second substrate on which the sensor unit 130 and the plurality of conductive patterns (including the first conductive pattern 120 and the second conductive pattern 122) are disposed. Namely, in FIG. 20, the second substrate (e.g., the upper substrate 150E) is disposed between the first substrate (e.g., a lower substrate 110E) and the circuit board 11.

As shown in FIG. 20, the sensor unit 130 and the plurality of conductive patterns (including the first conductive pattern 120 and the second conductive pattern 122) are disposed on, for example, a surface (e.g., an upper surface) of the upper substrate 150E away from the lower substrate 110E. The upper surface of the upper substrate 150E includes, for example, a first needle groove 151E and a second needle groove 152E in addition to the upper through hole 153, the upper through hole 154, the upper through hole 155 and upper through holes 156. The first conductive pattern 120 is disposed on the upper surface of the upper substrate 150E and extends into the first needle groove 151E. The second conductive pattern 122 is disposed on the upper surface of the upper substrate 150E and extends into the second needle groove 152E. The first adhesive pattern 124 is disposed between the first conductive pattern 120 and the upper substrate 150E, and the second adhesive pattern 126 is disposed between the second conductive pattern 122 and the upper substrate 150E. The first needle (e.g., a needle 161E) lands on the first conductive pattern 120 in the first needle groove 151E, and the second needle (e.g., a needle 162E) lands on the second conductive pattern 122 in the second needle groove 152E. As a result, the first needle (e.g., the needle 161E) and the second needle (e.g., the needle 162E) are shorter than other needles (e.g., the needle 163, the needle 164 and the needle 165) among the plurality of needles in the probe head assembly 10E. In addition, the lower substrate 110E disposed below the upper substrate 150E do not need the first needle groove 111A and the second needle groove 112A shown in FIG. 12. Moreover, the DUT 2A do not need the testing pad (or referred to as “bump”) 21 and the testing pad (or referred to as “bump”) 22 shown in FIG. 6 or FIG. 7, which helps to free up more space, allowing the density of chips on the DUT 2A to be further increased (if needed).

In embodiments shown in FIG. 20, the sensor 132 of the sensor unit 130 may be a non-contact temperature sensor (e.g., an infrared non-contact temperature sensor or the like) configured to measure temperature of objects (e.g., one of the needles or the space transformer 14) adjacent to the sensor 132, or the sensor 132 may be a distance sensor (e.g., a laser sensor, an ultrasonic sensor, a microwave sensor or the like) configured to measure the distance between the space transformer 14 and the upper substrate 150 to confirm the thermal expansion of the upper substrate 150 (when multiple sensors or sensor units are included).

In some embodiments, the first power transmission path (composed of the wiring 171 in the circuit board 11, the wiring 181 in the space transformer 14, the needle 161E and the first conductive pattern 120) and the second power transmission path (composed of the wiring 172 in the circuit board 11, the wiring 182 in the space transformer 14, the needle 162E and the second conductive pattern 122 can further be configured to transmit the measurement data to an automatic control system which adjusts and controls the voltage, current, and/or frequency parameters of the probe card assembly through testing software, which can improve the stability of the test system and prevent chips or the probe card assembly from burning out during the testing process. For example, the sensor 132 could detect distance between the space transformer 14 and the upper substrate 150, the measurement data can be transmitted to an automatic control system through the first power transmission path and the second power transmission path, the automatic control system then determine whether the thermal expansion of the upper substrate 150 exceeds a threshold value and then adjusts and controls the voltage, current, and/or frequency parameters of the probe card assembly 1E through testing software to prevent the probe head assembly 10E from being damaged during the testing process.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a probe head assembly includes a probe head structure, a sensor unit and a plurality of conductive patterns. The probe head structure includes a first substrate, a second substrate and a plurality of needles. The first substrate includes a plurality of needle holes. The second substrate is spaced apart from the first substrate and includes a plurality of needle holes corresponding to the plurality of needle holes of the first substrate. The plurality of needles extend through the plurality of needle holes of the first substrate and the plurality of needle holes of the second substrate. The sensor unit is mounted on the probe head structure. The plurality of conductive patterns are disposed on the probe head structure. The sensor unit is electrically connected to a first needle and a second needle among the plurality of needles through a first conductive pattern and a second conductive pattern among the plurality of conductive patterns, respectively.

In some embodiments, the sensor unit is mounted on the second substrate. The plurality of conductive patterns are disposed on the second substrate. The probe head assembly further includes a first adhesive pattern disposed between the first conductive pattern and the second substrate and a second adhesive pattern disposed between the second conductive pattern and the second substrate. In some embodiments, the first needle and the first conductive pattern contact in a first needle hole among the plurality of needle holes of the second substrate, and the second needle and the second conductive pattern contact in a second needle hole among the plurality of needle holes of the second substrate. In some embodiments, the second substrate further includes a first needle groove and a second needle groove. The first conductive pattern and the second conductive pattern are disposed in the first needle groove and the second needle groove, respectively. The first needle lands on the first conductive pattern in the first needle groove, and the second needle lands on the second conductive pattern in the second needle groove. In some embodiments, the sensor unit is disposed on a surface of the second substrate facing the first substrate. The second substrate is opaque to electromagnetic waves received by the sensor unit, and the second substrate further includes a sensor hole overlapped with the sensor unit. In some embodiments, a surface of the second substrate away from the first substrate includes a first conductive pattern groove, a second conductive pattern groove and a sensor groove. The first conductive pattern groove is connected between a first needle hole among the plurality of needle holes of the second substrate and the sensor groove. The second conductive pattern groove is connected between a second needle hole among the plurality of needle holes of the second substrate and the sensor groove. The sensor unit is disposed in the sensor groove. The first conductive pattern is disposed in the first conductive pattern groove and extends into the first needle hole. The second conductive pattern is disposed in the second conductive pattern groove and extends into the second needle hole. The first needle lands on the first conductive pattern in the first needle hole, and the second needle lands on the second conductive pattern in the second needle hole. In some embodiments, at least one of the first substrate and the second substrate is transparent to electromagnetic waves received by the sensor unit.

According to some embodiments, a probe card assembly includes a circuit board and a probe head assembly spaced apart from the circuit board. The probe head assembly includes a probe head structure, a sensor unit and a plurality of conductive patterns. The probe head structure includes a first substrate, a second substrate and a plurality of needles. The first substrate includes a plurality of needle holes. The second substrate is spaced apart from the first substrate and includes a plurality of needle holes corresponding to the plurality of needle holes of the first substrate. The plurality of needles extend through the plurality of needle holes of the first substrate and the plurality of needle holes of the second substrate. The sensor unit is mounted on the probe head structure. The plurality of conductive patterns are disposed on the probe head structure. The sensor unit is electrically connected to a first needle and a second needle among the plurality of needles through a first conductive pattern and a second conductive pattern among the plurality of conductive patterns, respectively.

In some embodiments, the circuit board includes a circuitry, and the first needle and the second needle are electrically connected to different wirings of the circuitry. In some embodiments, the probe card assembly further includes a space transformer disposed between the circuit board and the probe head assembly. The space transformer includes a circuitry. The first needle and the second needle are electrically connected to the different wirings of the circuitry of the circuit board through different wirings of the circuitry of the space transformer. A line pitch at a surface of the circuit board away from the space transformer is larger than a line pitch at a surface of the space transformer away from the circuit board. In some embodiments, the first substrate is disposed between the second substrate and the circuit board. In some embodiments, the second substrate is disposed between the first substrate and the circuit board. In some embodiments, the sensor unit is mounted on the second substrate. The plurality of conductive patterns are disposed on the second substrate. The probe head assembly further includes an adhesive pattern disposed between the first conductive pattern and the second substrate, between the second conductive pattern and the second substrate, or a combination thereof. A material of the adhesive pattern includes metals. In some embodiments, the first substrate and the second substrate are transparent to electromagnetic waves received by the sensor unit. The probe card assembly further includes a receiver unit disposed between the circuit board and the probe head assembly.

According to some embodiments, a probe head assembly includes a probe head structure, a sensor unit and a plurality of conductive patterns. The probe head structure includes a first substrate, a second substrate and a plurality of needles. The first substrate includes a plurality of needle holes. The second substrate is spaced apart from the first substrate and includes a plurality of needle holes corresponding to the plurality of needle holes of the first substrate. The plurality of needles extend through the plurality of needle holes of the first substrate and the plurality of needle holes of the second substrate. The sensor unit is mounted on the probe head structure. The plurality of conductive patterns are disposed on the probe head structure. The sensor unit is electrically connected to a first needle and a second needle among the plurality of needles through the plurality of conductive patterns, and the first needle and the second needle are shorter than other needles among the plurality of needles.

In some embodiments, the sensor unit is mounted on the second substrate, and the plurality of conductive patterns are disposed on the second substrate. In some embodiments, the probe head assembly further includes a plurality of adhesive patterns disposed between the plurality of conductive patterns and the second substrate. In some embodiments, the first needle and the second needle land on the plurality of conductive patterns, and the other needles extend through corresponding needle holes of the plurality of needle holes of the second substrate, respectively. In some embodiments, the first needle and the second needle are located on one of an upper side and a lower side of the second substrate, and the sensor unit is located on the other one of the upper side and the lower side of the second substrate. In some embodiments, the sensor unit and the plurality of conductive patterns are disposed in a plurality of grooves on a surface of the second substrate away from the first substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A probe head assembly, comprising:
a probe head structure comprising:
a first substrate comprising a plurality of needle holes;
a second substrate spaced apart from the first substrate and comprising a plurality of needle holes corresponding to the plurality of needle holes of the first substrate; and
a plurality of needles extending through the plurality of needle holes of the first substrate and the plurality of needle holes of the second substrate;
a sensor unit mounted on the probe head structure; and
a plurality of conductive patterns disposed on the probe head structure, wherein the sensor unit is electrically connected to a first needle and a second needle among the plurality of needles through a first conductive pattern and a second conductive pattern among the plurality of conductive patterns, respectively.

2. The probe head assembly as claimed in claim 1, wherein:
the sensor unit is mounted on the second substrate,
the plurality of conductive patterns are disposed on the second substrate, and
the probe head assembly further comprises:
a first adhesive pattern disposed between the first conductive pattern and the second substrate; and
a second adhesive pattern disposed between the second conductive pattern and the second substrate.

3. The probe head assembly as claimed in claim 1, wherein:
the first needle and the first conductive pattern contact in a first needle hole among the plurality of needle holes of the second substrate, and
the second needle and the second conductive pattern contact in a second needle hole among the plurality of needle holes of the second substrate.

4. The probe head assembly as claimed in claim 1, wherein:
the second substrate further comprises a first needle groove and a second needle groove,
the first conductive pattern and the second conductive pattern are disposed in the first needle groove and the second needle groove, respectively,
the first needle lands on the first conductive pattern in the first needle groove, and
the second needle lands on the second conductive pattern in the second needle groove.

5. The probe head assembly as claimed in claim 4, wherein:
the sensor unit is disposed on a surface of the second substrate facing the first substrate,
the second substrate is opaque to electromagnetic waves received by the sensor unit, and
the second substrate further comprises a sensor hole overlapped with the sensor unit.

6. The probe head assembly as claimed in claim 1, wherein:
a surface of the second substrate away from the first substrate comprises a first conductive pattern groove, a second conductive pattern groove and a sensor groove,
the first conductive pattern groove is connected between a first needle hole among the plurality of needle holes of the second substrate and the sensor groove,
the second conductive pattern groove is connected between a second needle hole among the plurality of needle holes of the second substrate and the sensor groove,
the sensor unit is disposed in the sensor groove,
the first conductive pattern is disposed in the first conductive pattern groove and extends into the first needle hole,
the second conductive pattern is disposed in the second conductive pattern groove and extends into the second needle hole,
the first needle lands on the first conductive pattern in the first needle hole, and
the second needle lands on the second conductive pattern in the second needle hole.

7. The probe head assembly as claimed in claim 1, wherein at least one of the first substrate and the second substrate is transparent to electromagnetic waves received by the sensor unit.

8. A probe card assembly, comprising:
a circuit board; and
a probe head assembly spaced apart from the circuit board and comprising:
a probe head structure comprising:
a first substrate comprising a plurality of needle holes;
a second substrate spaced apart from the first substrate and comprising a plurality of needle holes corresponding to the plurality of needle holes of the first substrate; and
a plurality of needles extending through the plurality of needle holes of the first substrate and the plurality of needle holes of the second substrate;
a sensor unit mounted on the probe head structure; and
a plurality of conductive patterns disposed on the probe head structure, wherein the sensor unit is electrically connected to a first needle and a second needle among the plurality of needles through a first conductive pattern and a second conductive pattern among the plurality of conductive patterns, respectively.

9. The probe card assembly as claimed in claim 8, wherein the circuit board comprises a circuitry, and the first needle and the second needle are electrically connected to different wirings of the circuitry.

10. The probe card assembly as claimed in claim 9, further comprising:
a space transformer disposed between the circuit board and the probe head assembly, wherein:
the space transformer comprises a circuitry,
the first needle and the second needle are electrically connected to the different wirings of the circuitry of the circuit board through different wirings of the circuitry of the space transformer,
a line pitch at a surface of the circuit board away from the space transformer is larger than a line pitch at a surface of the space transformer away from the circuit board.

11. The probe card assembly as claimed in claim 8, wherein the first substrate is disposed between the second substrate and the circuit board.

12. The probe card assembly as claimed in claim 8, wherein the second substrate is disposed between the first substrate and the circuit board.

13. The probe card assembly as claimed in claim 8, wherein:
the sensor unit is mounted on the second substrate,
the plurality of conductive patterns are disposed on the second substrate, and
the probe head assembly further comprises:
an adhesive pattern disposed between the first conductive pattern and the second substrate, between the second conductive pattern and the second substrate, or a combination thereof,
wherein a material of the adhesive pattern comprises metals.

14. The probe card assembly as claimed in claim 8, wherein the first substrate and the second substrate are transparent to electromagnetic waves received by the sensor unit, and the probe card assembly further comprises:
a receiver unit disposed between the circuit board and the probe head assembly.

15. A probe head assembly, comprising:
a probe head structure comprising:
a first substrate comprising a plurality of needle holes;
a second substrate spaced apart from the first substrate and comprising a plurality of needle holes corresponding to the plurality of needle holes of the first substrate; and
a plurality of needles extending through the plurality of needle holes of the first substrate and the plurality of needle holes of the second substrate;
a sensor unit mounted on the probe head structure; and
a plurality of conductive patterns disposed on the probe head structure, wherein the sensor unit is electrically connected to a first needle and a second needle among the plurality of needles through the plurality of conductive patterns, and the first needle and the second needle are shorter than other needles among the plurality of needles.

16. The probe head assembly as claimed in claim 15, wherein:
the sensor unit is mounted on the second substrate, and
the plurality of conductive patterns are disposed on the second substrate.

17. The probe head assembly as claimed in claim 16, further comprising:
a plurality of adhesive patterns disposed between the plurality of conductive patterns and the second substrate.

18. The probe head assembly as claimed in claim 16, wherein:
the first needle and the second needle land on the plurality of conductive patterns, and
the other needles extend through corresponding needle holes of the plurality of needle holes of the second substrate, respectively.

19. The probe head assembly as claimed in claim 16, wherein:
the first needle and the second needle are located on one of an upper side and a lower side of the second substrate, and
the sensor unit is located on the other one of the upper side and the lower side of the second substrate.

20. The probe head assembly as claimed in claim 16, wherein:
the sensor unit and the plurality of conductive patterns are disposed in a plurality of grooves on a surface of the second substrate away from the first substrate.
